(19) United States
(12) Patent Application Publication
(10) Pub. No.: US 2026/0372168 A1
(43) Pub. Date: Nov. 19, 2026

(54) Method, Mould, and Housing for Forming an Electronic Component Package

(71) Applicant: Besi Netherlands B.V., Duiven (NL)

(72) Inventors: Wilhelmus Gerardus Joseph Gal, Braamt (NL); Sebastianus Hubertus Maria Kersjes, Lent (NL)

(21) Appl. No.: 19/121,889

(22) PCT Filed: Oct. 6, 2023
(86) PCT No.: PCT/NL2023/050523

§ 371 Date: Apr. 17, 2025

(30) Foreign Application Priority Data
Oct. 20, 2022 (NL) 2033364

(51) Int. Cl. H10W 74/01; H10W 74/47; H10W 76/01; H10W 76/18

(52) U.S. Cl. CPC H10W 74/016; H10W 76/01; H10W 76/18; H10W 74/47

(57) ABSTRACT

The present invention relates to a method for forming an electronic component package including providing and placing a housing on the carrier whereon the electronic component is mounted, as such that the electronic component is located in an opening of the housing, and introducing a moulding material surrounding the housing to provide a moulded electronic component package. The invention also relates to a housing with at least one enclosed opening for holding an electronic component and the use of such a housing in that method, as well as to the resulting moulded electronic component package.

### CROSS-REFERENCE TO RELATED APPLICATIONS

This application is the United States national phase of International Patent Application No. PCT/NL2023/050523 filed Oct. 6, 2023, and claims priority to The Netherlands Patent Application No. 2033364 filed Oct. 20, 2022, the disclosures of which are hereby incorporated by reference in their entireties.

### BACKGROUND OF THE INVENTION

Field of the Invention The present invention relates to a method for forming an electronic component package.

The invention also relates to a housing with at least one enclosed opening for holding an electronic component and the use of such a housing in that method, as well as to the resulting moulded electronic component package.

### Description of Related Art

Electronic components are used on a huge scale and can for instance be formed by diodes (for example, light emitting diodes or LEDs), transistors, integrated circuits (IC/chips), chip-based sensors for detecting force, pressure, fingerprint, light and images, and chip-based actuators (MEMS; microelectromechanical systems) and/or other types of semiconductors. The electronic components may typically be mounted on a carrier, also referred to as a substrate. The carrier can be formed by, but not limited to, a wafer, a lead frame, or a (printed circuit) board.

When incorporating carrier based electronic components in electronic equipment it is often required to at least partially shield (encapsulate) the electronic component for which reason a housing may be moulded around the electronic component. The electronic component may be fully embedded in such moulded housing but for the functionality of the electronic component the component may also be left at least party free of the housing to allow access to the electronic component e.g. for detection purposes and/or to cool the electronic component during use. At least partially not covered electronic components are also referred as “bare die”. The electronic components to be moulded are normally in larger groups embedded in hardened moulding material (encapsulating material) while after hardening of the encapsulating material the encapsulated (moulded) electronic components forming an electronic component package may be singulated, for instance by sawing the encapsulating material and the carrier resulting in individualised electronic components.

To further control the access to moulded electronic components and/or to keep the electronic components at least partially free of encapsulating material also a housing may be placed around, against or over the electronic components. The prior art for instance shows a semiconductor package comprising a housing or an opening/cavity being placed along or over the electronic component. For example, US20220093664A1 and US20220093482A1 disclose a protective cover disposed over a sensor region of the die and attached to the die by a cover adhesive. The package includes a dam structure configured to protect components of the semiconductor package from contamination. The dam structure may be applied by printing epoxy on top of the carrier and then being cured thereafter.

Problems of the prior art electronic component package wherein a housing is used to at least partially keep an electronic component mounted on a carrier free of encapsulating material are that the use of a housing to keep moulded electronic components at least partially free of the moulding (encapsulating) material may lead to tensions in the final product; that it is difficult to mould the electronic components at least partially covered by housings with high precision as the quality of the moulding process is sensitive to the sizing of the housing, that the housing in the encapsulated product may interact with the working of the encapsulated electronic component; and/or that the prior art solutions are relatively expensive.

### SUMMARY OF THE INVENTION

Hence, the goal of the present invention is to overcome these disadvantages and provide an electronic component package of the specified type, as well as the method to produce such package, wherein the final product has at least the advantageous specifications of the prior art electronic component packages wherein housings are used that are easier and/or cheaper to produce and/or have a better quality.

To solve these problems the present invention provides a method for forming an electronic component package, comprising the steps of: A) providing at least one housing with at least one enclosed opening for an electronic component, which housing is at least partially made out of a partially cured moulding material; B) placing the partially cured housing on a carrier comprising at least one electronic component mounted on the carrier such that the housing encloses the electronic component mounted on the carrier; C) placing the carrier in a mould, such that the carrier and the at least one electronic component lie between a contact surface of a first mould part and a contact surface of a second mould part; D) moving the mould parts toward each other and holding the mould parts in a closed position under the influence of a closing force, whereby at least one mould cavity in the contact surface of at least one of the mould parts encloses the electronic component and the housing; E) introducing a liquid moulding material into the at least one mould cavity, such that the liquid moulding material fills the mould cavity leaving the at least one housing opening free of moulding material; F) allowing the liquid moulding material to at least partially cure and integrate with at least a part of the at least one housing to form an electronic component package; and G) moving the mould parts apart and taking the electronic component package out of the mould. By using a housing with an opening that is at least partially made out of a partially cured moulding material to shield an electronic component the final product (the housing) after curing of the moulding material and the housing is made from an integrated material that allows for instance subsequent singulation (or other processing of the package and/or carrier) with a minimal risk of uncontrolled package parts coming loose as the package is now formed by an integrated (hardened moulding) material. Also unwanted interference of a housing with at least one electronic component enclosing opening with the (later) moulded part of the package is banned with the method according to the present invention. A further advantage is that the present invention is supportive in providing electronic component packages with a uniform height; as at least a part of the housing enclosing the electronic component is only partially cured during processing step D) the choice may be made to introduce the housing with a slightly higher height between the mould parts. This enables that the step of closing the mould halves is also used to bring the (at least one) housing to the height of the rest of the package to be moulded. It is even feasible to align different heights of housings. The invention is also supportive in the global trend of electronic component further miniaturization. The method for forming a package according to the invention is also supportive in making the moulding process more reliable than the prior art electronic component moulding methods. A further advantage of placing at least one partially cured housing on the carrier before introducing the liquid moulding material into the at least one mould cavity is that the partially cured housing(s) may act as (a) flow guide to influence (steer) the flow of the liquid moulding material in a mould cavity and so to enhance the moulding quality.

As defined herein, a contact surface of a first mould part or a second mould part is not limited to a surface of a mould part that directly contacts the carrier when the mould parts are held in a closed position. The contact surface can also include a surface of the mould cavity that can be in direct contact with the housing and/or the liquid moulding material.

The (liquid) moulding material according to the present invention may comprise a (thermos-curing) polymer, such as an epoxy resin, or epoxy moulding compound (EMC), and optionally provided with a filler material or a silicone-based encapsulating material.

During the placing of the partially cured housing on the carrier-such that the housing encloses the electronic component mounted on the carrier (processing step B) the partially cured material of the housing may comprise a B-stage cured material. This implies that at least a part of the housing material is partially or shortly cured but at least partially shape-retaining. The B-stage (preferably epoxy) material may be shaped at one location, and the subsequent curing (including any potential adherence) may be performed at another location, with a mean time of second up to days.

It is possible to form the housing in a dedicated housing mould, and after a limited time of (partial B-stage) curing, the housing may be taken from the housing mould. Alternatively or subsequently the housing may be (further) shaped by means of for instance etching, (laser-)cutting, or any other machining technique.

The moulding process may be performed by transfer moulding, for which purpose the encapsulating material is brought into a liquid state by heating. Alternatively, the moulding process of the electronic component packages may also be arranged by compression moulding, wherein the moulding material is introduced into the mould cavity before the mould halves are closed. After the encapsulating material has at least partially cured (chemically), the mould halves are opened and the carrier with moulded electronic components may be removed from the mould. An optional next step is the singulation process, wherein the moulded electronic components are separated/singulated/diced, for example, by means of cutting or sawing. These processes are well known in the art. The present invention may also be beneficial in minimising the shear forces in semiconductor packages during a singulation operation.

During processing step D) at least one of the mould parts may contact the housing. This provides the advantage that the housing remains more firmly in place during any subsequent step, such as during introducing of a liquid moulding material.

Preferably, the partially cured moulding material of the housing, in particular prior to partial curing, and the liquid moulding material introduced in step E) are a same material. This results in optimal integration of the housing and the surrounding moulding material. As such, the housing and surrounding moulding material appear, and have the characteristics of a single moulded object.

The present invention also relates to the housing with at least one enclosed opening for holding an electronic component mounted on a carrier, which housing is at least partially made of a partially cured moulding material, and which opening borders a flat contact side to be placed onto a carrier. With such a housing the advantages may be realised as already listed above in relation to the method for forming a package according to the present invention and are here identically included in relation to the housing according to the present invention. In specific embodiments, at least a part of the housing may comprise B-stage cured material, and/or the moulding material comprises epoxy or EMC. The partially cured housing is preferably limited deformable or in a pliable state and/or the housing may for instance comprise a shape of a ring or any other form-fitting structure. The housing may also comprise any geometrical shape, such as for instance the shape of a circle, rectangle, square, ellipse, triangle, parallelogram, trapezoid, polygon, pentagon, hexagon, heptagon, octagon, or decagon. It is also possible that the at least one opening comprises a continuous or, alternatively, a variable width e.g. a bottom width that differs from the top width. The said opening is to be kept substantially free of moulding material, thus at least partially shielding an electronic component included in it from moulding material. It is also possible to also place more than one electronic component in a single housing opening. In a further embodiment, a single housing comprises a plurality of housing openings. It is feasible that two or more housings are interconnected, for instance by a connector e.g. a bridge. An advantage of plural opening housings is that the placement or attachment of such a housing on a carrier may be efficient.

In yet another embodiment, the housing may comprise a top cover. Such a top cover may for instance be made of a material chosen from the group of epoxy, EMC, glass, silicon, metal, foil, thin film, and other possible suitable materials. Preferably, the top cover may also be made from a B-stage epoxy material but also a fully cured material may be applied for the top cover. The top cover may be formed during forming or the rest of the housing or may be assembled after the further part of the housing is produced, or even after a part of the housing is attached to the carrier and even after the package has been moulded. The top cover may function as a protective cover, shielding it against physical contact, light, temperature, fluids, gasses or contaminants. Sensors to be shielded against physical contact are for instance: micro-heater plates, graph-based sensors, or a combination of these two. The top cover may also function to cover light-sensitive or image sensors. The top cover may be substantially transparent, or opaque, for protecting non-light-sensitive sensors. It is also an option to make the top cover from metal, as such providing electromagnetic shielding of an electronic component. A top cover may be attached by an adhesive, like for instance a (B-stage cured) epoxy material.

The top cover may fully close the top of the opening such that the housing resembles a closed cap for the electronic component to be placed inside the opening. In another embodiment, the top cover may also be provided with at least one aperture. The aperture may function as a pressure relieving path and maintain the moisture sensitivity level (MSL) in the opening, in case the electronic component gets heated, therefore a popcorn effect may be prevented. The popcorn effect is when the electronic component “pops” because the moisture inside the package expands in the reflow process. Such aperture(s) may be formed also during the shaping of the housing. The top cover with aperture(s) may fully cover the top portion opening in such a way that the housing forms a perforated cap for the electronic component.

The housing may be placed around the electronic component outside the mould, or alternatively, the placing may occur inside the mould. The housing may stick on the carrier of the electronic component by itself (as a material property of a partly cured moulding material) or an additional adhesive material may be used, but it is also possible to mould or print the housing directly on top of the carrier.

The present invention also comprises the use of the housing with at least an enclosed opening for an electronic component mounted on a carrier according to the invention in the method for forming a package on a carrier according to the invention. With such use the advantages may be realised as already listed above in relation to the method for forming a package and the housing according to the present invention and are here identically included in relation to the use of the housing according to the present invention.

The housing may be open at the flat contact side, wherein the housing comprises at least one raised edge enclosing the enclosed opening. Additionally, a thickness of the at least one raised edge may range from 0.05-5 mm, preferably 0.05-2.5 mm, more preferably 0.05-1.0 mm. Additionally or alternatively, a height of the housing may range from 0.1-10 mm, preferably 0.1-2 mm, and/or a width of the housing may range from 1 to 50 mm, preferably 2-20 mm.

The housing may comprise at least one raised edge enclosing the enclosed opening, wherein the raised edge may have a shape selected from circular, ellipsoid, triangular, square, rectangular, polygonal, honeycomb, kite, and trapezoid. The geometrical shapes described for the housing hereinabove may also apply to the at least one raised edge.

The present invention also relates to an electronic component package comprising: a carrier whereon at least one electronic component is mounted that is enclosed by at least one housing according to the present invention, which housing is attached to the carrier; and surrounding moulding material attached to the carrier, which surrounding moulding material is surrounding the at least one housing; wherein the surrounding moulding material and the housing are fully cured; wherein the surrounding moulding material and at least a part of the at least one housing are made out of a same material, and wherein the surrounding moulding material and the material of the at least one housing are integrated. The surrounding moulding material leaves at least one housing opening free of moulding material; thus preventing the at least one electronic component to be fully embedded in the moulding material. Typically, the liquid moulding material is during at least partial curing integrating with the material of the housing placed on the carrier. This integration may occur due to the partially (B-staged) cured housing and the liquid moulding material—at least partially—curing when in contact with each other, resulting in a strong mating of at least a part of the housing and the surrounding moulding material. One of the advantages of this invention is that it leads to an integration of a least a part of the housing and the surrounding moulding material, resulting in a solidly composed package.

As herein described, the same material is a material that are substantially the same. In practice, there will be differences between the moulding material of the housing and the surrounding moulding material. The moulding material of the housing may for example be manufactured in a different batch as compared to the surrounding moulding material. As such, both moulding materials are intended to be the same, but there will be slight differences between both materials, due to variation in production processes, variation in raw materials, etc. As the housing is partially cured (i.e. present in a B-stage), it will have a different molecular composition as compared to a non-cured, or liquid moulding material of the surrounding moulding material. The B-stage moulding material is likely to contain more crosslinks as compared to liquid moulding material. Nevertheless, in this case both moulding materials are still considered the same.

Furthermore, minor additives to either the moulding material of the housing or the surrounding moulding material will not render both moulding materials different from each other. Minor additives can for example be dyes, fillers, or compounds that speed up, slow down, or otherwise affect the rate at which moulding material cures. As long as an additive does not substantially affect the integration of the moulding material of the housing and the surrounding moulding material, both moulding materials are considered the same.

Integration, or integrated, as defined herein, means that at least some crosslinks and/or bonds are formed between the moulding material of the housing and the surrounding moulding material. These crosslinks and/or bonds may be covalent.

The moulding material of the at least part of the housing and the surrounding moulding material may be fused. Fused, as defined herein, means that crosslinks and/or bonds are formed between the moulding material of the housing and the surrounding moulding material. In addition, for fused materials, material at a cross section of an interface between the housing and the surrounding moulding material compared to material at a cross section of either the housing or the surrounding moulding material at a location other than the interface, will be indistinguishable from each other.

The present invention further provides an electronic component package obtainable by the method according to the present invention. As the housing can be cut from partially cured moulding material, using for example a laser, outer surfaces of the housing are very smooth and do not contain any, or hardly any burrs. As such, a demarcation between moulded parts of the electronic component package and unmoulded parts is free from burrs and irregularities. A lining of a mould could for example be used to shield an electronic component from liquid moulding material during transfer moulding. However, this will result in irregularities being formed at the demarcation or interface between the shielded electronic component which is free from moulding material, and the surrounding moulded parts, due to the flow and pressure of the liquid moulding material enacted on the part of the lining that shields the electronic components. As such, the present invention provides a significant improvement over the prior art.

It is imaginable that the carrier comprises a plurality of housings, and/or housings with a plurality of different housing embodiments. Preferably such a plurality of housings on a single carrier have substantially a similar height.

### BRIEF DESCRIPTION OF THE DRAWINGS

The terms Fig., Figs., Figure, and Figures are used interchangeably in the specification to refer to the corresponding figures in the drawings.

The invention will be further elucidated on the basis of the non-limitative exemplary embodiments shown in the following figures. Corresponding elements are designated in the figures with corresponding reference numerals. Herein shows:

FIG. 1 a cross-sectional view of a moulded electronic component package comprising a housing according to the present invention;

FIGS. 2a-2d cross-sectional views of alternative embodiments of moulded electronic component packages comprising a housing with top covers;

FIGS. 3a and 3b top views on a carrier with electronic components that are enclosed by partially cured housings before and after moulding material has been supplied; and

FIG. 4 schematic represented steps of the method according to the present invention.

### DESCRIPTION OF THE INVENTION

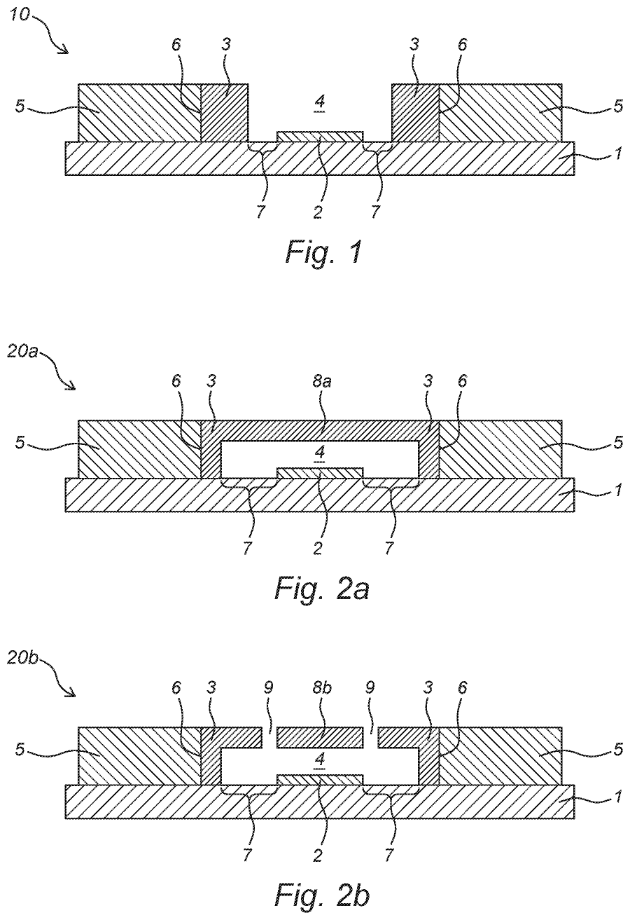

FIG. 1 shows an embodiment of an electronic component package (10). A carrier (1) is shown with an electronic component (2) mounted on it, wherein the electronic component (2) is surrounded by the housing (3) comprising an opening (4). The electronic component (2) is placed in the opening (4). It is apparent that the housing (3) is higher than the electronic component (2) in this embodiment. Initially the housing (3) comprised a partially cured material, preferably comprising epoxy or EMC. A (surrounding) moulding material (5) is introduced in a mould cavity (not shown here) such that it is allocated onto specific areas on the carrier (1). The moulding material (5) is only added after placement of the housing (3) on the carrier (1). Typically, the moulding material (5) comprises epoxy or EMC. Once the electronic component package (10) is at least partially cured, the housing (3) and the moulding material (5) at least partially fuse or integrate at their contact surfaces (6). At these contact surfaces (6) a strong bond is realised between the housing (3) and the moulding material (5) as they are made from a similar material. The contact surfaces (6) might be even be indistinguishable once the curing (and integration) process of the moulding material (5) is complete. It is possible that there is a free space (7) on the carrier between the electronic component (2) and the housing (3). In other embodiments, the electronic component (2) and the housing (3) may be placed into contact with each other, or the electronic component (2) may be placed in a more lateral portion and partially covered by the housing (3). In yet another embodiment more than one electronical component (2) are placed in the opening (4).

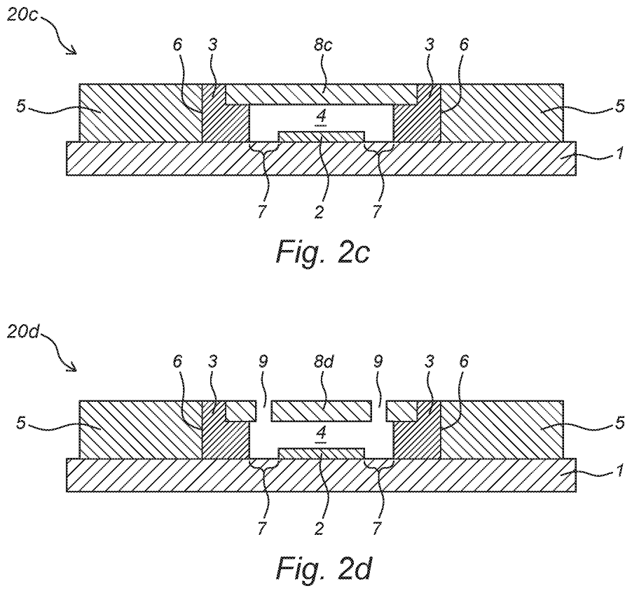

FIGS. 2a-2d show exemplary embodiments of electronic component packages (20a 20d) comprising different types of top covers (8a-8d). In the electronic component package (20a) shown in FIG. 2a the housing (3) comprises a top cover (8a). The top cover (8a) is made out of the same material as the housing (3). and is integrally formed with the rest of the housing (3). Alternatively the top cover (8a) may also be attached to the housing (3) after the shaping a part of the housing (3). The top cover (8a) is shown as completely covering the opening (4) as such the housing (3) resemble a cap for the electronic component inside the opening. The top cover (8a) may shield the electronic component (2) from for instance light, contaminants or physical impact.

In the embodiment shown in FIG. 2b, an electronic component package (20b) comprises a top cover (8b) including two apertures (9). The apertures (9) facilitate atmospheric exchange between the opening (4) and the surroundings of the electronic component package (20b), for example, to release gas or pressure when the electronic component (2) is heated or to allow a gas access to the electronic component to be detected. The top cover (8b) comprises two apertures (9) which may be formed together during the shaping of the housing (3) or drilled later on.

In the embodiment as shown in FIG. 2c, an electronic component package (20c) comprises a top cover (8c), which top cover (8c) is made from a different material than the rest (raised edge) of the housing (3). The top cover (8c) may for instance be transparent or opaque and/or act as a lens to allow light access to the electronic component (4).

In the electronic component package (20d) as shown in FIG. 2d a top cover (8d) has apertures (9). The top cover (8d) is attached to the rest of the housing (3) on a lateral portion of the top cover (8d) and at least a part of the housing (3).

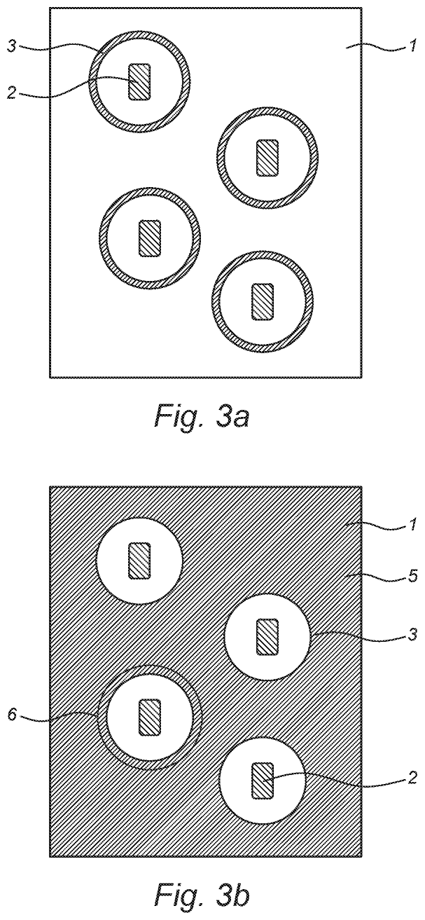

FIGS. 3a and 3b show top views on a carrier (1) with electronic components (2) that are enclosed by housings (3) before and after moulding material (5) has been supplied, respectively. In FIG. 3a four housings (3) are placed on the carrier (1), each (circle-shaped) housing enclosing a plurality of electronic components (2). In FIG. 3b the same carrier (1), electronic components (2) and housings (3) are shown as depicted in FIG. 3a, but in FIG. 3b a moulding material (5) has been supplied by a moulding process. A visible transition (6) still remains between the housings (3) and the moulding material (5) after the moulding material (5) is supplied, however along the contact surface of the housings (3) and the moulding material (5) the material of the housings (3) and the moulding material (5) are integrated while curing. Once the moulding material (5) and the housings (3) are fully cured, the electronic components (2) may be separated from each other with a singulation process.

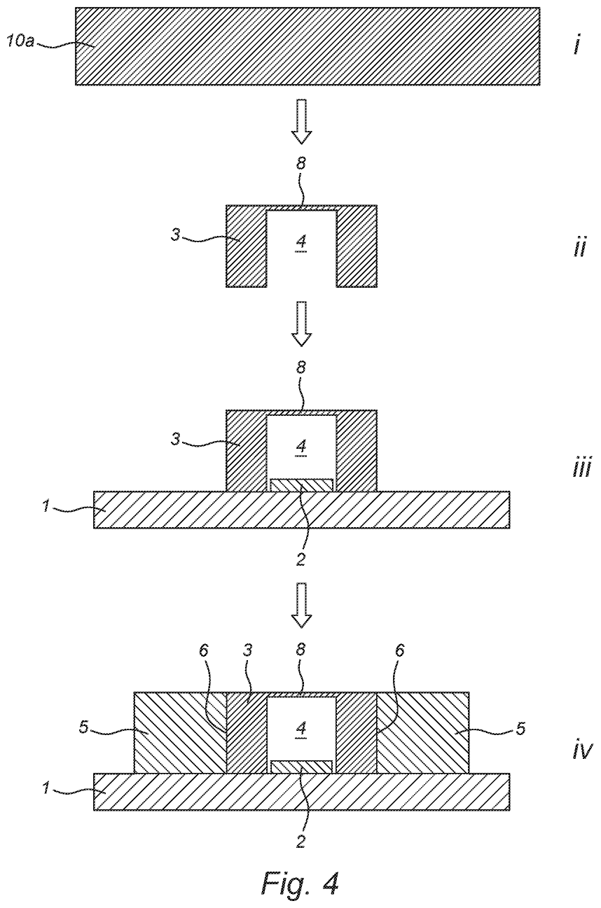

FIG. 4 shows schematic represented steps of a method according to the present invention. In a first step i) a partially cured basic element (10a) made out of moulding material is formed, while in step ii) out of the partially cured basic element (10a) a housing (3) is formed, e.g. by machining and/or laser cutting. A top cover (8) may be formed integrally with the rest of the housing (3) or may be added to a housing part cut out of the basic element (10a). In step iii) the housing (3) is placed onto the carrier (1), wherein an electronic component (2) is located in the opening (4) of the housing (3). Any suitable adhesive may be used to place the housing (3) on the carrier (1) but alternatively the adhesive strength of the partially cured housing may be used to attach the housing (3) onto the carrier (1). In step iv) a moulding material (5) is allocated (moulded) at the surrounding of the housing (3), after which process the moulding material (5) and the partially cured part of the housing (3) are cured such that the housing (3) is integrated with the surrounding moulding material (5).

The verb “comprise” and its conjugations as used in this patent document are understood to mean not only “comprise”, but to also include the expressions “contain”, “substantially contain”, “formed by” and conjugations thereof.

1. A method for forming an electronic component package, comprising the steps of:
A) providing at least one housing with at least one enclosed opening for an electronic component, which housing is at least partially made out of a partially cured moulding material;
B) placing the partially cured housing on a carrier comprising at least one electronic component mounted on the carrier such that the housing encloses the electronic component mounted on the carrier;
C) placing the carrier in a mould, such that the carrier and the at least one electronic component lie between a contact surface of a first mould part and a contact surface of a second mould part;
D) moving the mould parts toward each other and holding the mould parts in a closed position under the influence of a closing force, whereby at least one mould cavity in the contact surface of at least one of the mould parts encloses the electronic component and the housing;
E) introducing a liquid moulding material into the at least one mould cavity, such that the liquid moulding material fills the mould cavity leaving the at least one housing opening free of moulding material;
F) allowing the liquid moulding material to at least partially cure and integrate with at least a part of the at least one housing to form an electronic component package; and
G) moving the mould parts apart and taking the electronic component package out of the mould.

2. The method according to claim 1, wherein the partially cured material of the housing during processing step B) comprises B-stage cured material.

3. The method according to claim 1, wherein the moulding material comprises epoxy and/or an epoxy moulding compound (EMC).

4. The method according to claim 1, wherein the moulding process is performed by transfer moulding or compression moulding.

5. (canceled)

6. The method according to claim 1, wherein the partially cured moulding material of the housing, in particular prior to partial curing, and the liquid moulding material introduced in step E) are a same material.

7. A housing with at least one enclosed opening for holding an electronic component mounted on a carrier, which housing is at least partially made of a partially cured moulding material and which opening borders a flat contact side to be placed onto a carrier.

8. The housing according to claim 7, wherein the partially cured material comprises B-stage cured material.

9. The housing according to claim 7, wherein the moulding material comprises epoxy and/or an epoxy moulding compound (EMC).

10. (canceled)

11. The housing according to claim 7, wherein the housing comprises a top cover facing away from the contact side of the housing.

12. The housing according to claim 11, wherein the top cover comprises at least one aperture.

13. The housing according to claim 11, wherein the top cover is made of a material chosen from the group of epoxy, an epoxy moulding compound (EMC), glass, silicon and metal.

14. The housing according to an claims 7, wherein the housing comprises a plurality of housing openings.

15-18. (canceled)

19. An electronic component package comprising:
a carrier whereon at least one electronic component is mounted that is enclosed by
at least one housing according to claim 7, which housing is attached to the carrier; and
surrounding moulding material attached to the carrier, which surrounding moulding material is surrounding the at least one housing,
wherein the surrounding moulding material and the housing are fully cured;
wherein the surrounding moulding material and at least a part of the at least one housing are made out of a same material, and
wherein the surrounding moulding material and at least a part of the material of the at least one housing are integrated.

20. The electronic component package according to claim 19, wherein the moulding material of the at least part of the housing and the surrounding moulding material are fused.

21. The electronic component package obtainable by the method according to claim 1.
